(19) United States
(12) Patent Application Publication
(10) Pub. No.: US 2023/0019645 A1
(43) Pub. Date: Jan. 19, 2023

(54) NITRIDE SEMICONDUCTOR LASER ELEMENT

(71) Applicant: Nuvoton Technology Corporation Japan, Kyoto (JP)

(72) Inventors: Hideo KITAGAWA, Toyama (JP); Shinji YOSHIDA, Shiga (JP)

(21) Appl. No.: 17/951,000

(22) Filed: Sep. 22, 2022

Related U.S. Application Data
(63) Continuation of application No. PCT/JP2021/011639, filed on Mar. 22, 2021.

(30) Foreign Application Priority Data
Mar. 30, 2020 (JP) 2020-060225

(51) Int. Cl. H01S 5/343; H01S 5/028

(52) U.S. Cl. CPC H01S 5/34333; H01S 5/028

(57) ABSTRACT

A nitride semiconductor laser element includes a stacked structure and a dielectric multilayer film, The dielectric multilayer film includes a first dielectric film, a second dielectric film, and a third dielectric film in the stated order. The nitride semiconductor laser element satisfies the following expressions:

$$\sum nk \times dk + ni \times di + nj \times dj = m 1 \times \frac{λ}{4} \pm \frac{λ}{16} ;$$

$$nj \times dj = m 2 \times λ / 4 \pm λ / 16 ; and$$

$$\frac{3 λ}{16} ≦ \sum nk \times dk ≦ \frac{5 λ}{16} .$$

### CROSS REFERENCE TO RELATED APPLICATIONS

This is a continuation application of PCT International Application No. PCT/JP2021/011639 filed on Mar. 22, 2021, designating the United States of America, which is based on and claims priority of Japanese Patent Application No. 2020-060225 filed on Mar. 30, 2020. The entire disclosures of the above-identified applications, including the specifications, drawings and claims are incorporated herein by reference in theft entirety.

### FIELD

The present disclosure relates to a nitride semiconductor laser element.

### BACKGROUND

Conventionally, a semiconductor laser element that emits laser light has end faces (a front end face and a rear end face) on which reflective films are formed for causing laser light to resonate inside the semiconductor laser element and for the resonated laser light to be appropriately emitted from the semiconductor laser element (for example, see Patent Literature (PTL) 1).

### CITATION LIST

### Patent Literature

### PTL 1: Japanese Unexamined Patent Application Publication No. 2010-219436

### SUMMARY

### Technical Problem

There are cases where reflective films formed on end faces of a semiconductor laser element deform due to absorption of laser light emitted from the semiconductor laser element. Deformation of the reflective films changes an optical property, such as a change in the transmittance and reflectance of the laser light.

The present disclosure provides a nitride semiconductor laser element that can prevent a change in an optical property.

### Solution to Problem

A nitride semiconductor laser element according to one aspect of the present disclosure is a nitride semiconductor laser element that includes: a stacked structure that includes a plurality of semiconductor layers including a waveguide, and has a pair of resonator end faces that are opposed to each other; and a dielectric multilayer film disposed on a light-emitting end face of the pair of the resonator end faces, the light-emitting end face being a resonator end face from which light is emitted. The dielectric multilayer film includes a first dielectric film, a second dielectric film, and a third dielectric film in a stated order from a light-emitting end face side.

The first dielectric film includes n protective films from a first protective film up to an n^{th} protective film in a stated order from the light-emitting end face side, where n is a positive integer. The following expressions are satisfied:

$$\sum nk \times dk + ni \times di + nj \times dj = m 1 \times \frac{λ}{4} \pm \frac{λ}{16} ; \qquad [ Math . 1 ]$$

$$nj \times dj = m 2 \times λ / 4 \pm λ / 16 ; and$$

$$\frac{3 λ}{16} ≦ \sum nk \times dk ≦ \frac{5 λ}{16} , \qquad [ Math . 2 ]$$

where (i) a refractive index and a film thickness of a k^{th} protective film in the first dielectric film are denoted by nk and dk, respectively, where k is an integer satisfying 1≤k≤n, (ii) a refractive index and a film thickness of the second dielectric film are denoted by ni and di, respectively, (iii) a refractive index and a film thickness of the third dielectric film are denoted by nj and dj, respectively, (iv) m1 is an integer of at least 2, and (v) m2 is a positive integer.

A nitride semiconductor laser element according to one aspect of the present disclosure is a nitride semiconductor laser element that includes: a stacked structure that includes a plurality of semiconductor layers including a waveguide, and has a pair of resonator end faces that are opposed to each other; and a dielectric multilayer film disposed on a light-emitting end face of the pair of the resonator end faces, the light-emitting end face being a resonator end face from which light is emitted. The dielectric multilayer film includes a first dielectric film, a second dielectric film, and a third dielectric film in a stated order from a light-emitting end face side. The first dielectric film includes n protective films from a first protective film up to an n^{th} protective film in a stated order from the light-emitting end face side, where n is a positive integer. The following expressions are satisfied:

$$\sum nk \times dk + ni \times di + nj \times dj = m 1 \times \frac{λ}{4} \pm \frac{λ}{16} ; and \qquad [ Math . 3 ]$$

$$nj \times dj = m 2 \times λ / 4 \pm λ / 16 ,$$

where (i) a refractive index and a film thickness of a k^{th} protective film in the first dielectric film are denoted by nk and dk, respectively, where k is an integer satisfying 1≤k≤n, (ii) a refractive index and a film thickness of the second dielectric film are denoted by ni and di, respectively, (iii) a refractive index and a film thickness of the third dielectric film are denoted by nj and dj, respectively, (iv) m1 is an integer of at least 2, and (v) m2 is a positive integer. One of the second dielectric film and the third dielectric film has a property that a film thickness decreases due to laser light emitted from the nitride semiconductor laser element, and an other of the second dielectric film and the third dielectric film has a property that a film thickness increases due to the laser light emitted from the nitride semiconductor laser element.

### Advantageous Effects

The present disclosure can provide a nitride semiconductor laser element that can prevent a change in an optical property.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross sectional view schematically illustrating a configuration of a nitride semiconductor laser element according to an embodiment.

FIG. 2 is a diagram schematically illustrating one example of deformation of dielectric films when the nitride semiconductor laser element according to the embodiment emits laser light.

FIG. 3 is a graph showing reflectances of a dielectric multilayer film relative to wavelengths of a nitride semiconductor laser element according to a comparative example.

FIG. 4 is a cross sectional view schematically illustrating the nitride semiconductor laser element according to the embodiment which is taken along line IV-IV shown in FIG. 1.

FIG. 5 is a table showing changes in film thicknesses according to conditions for performance of aging.

FIG. 6A is a graph showing reflectances relative to film thicknesses of a dielectric multilayer film included in the nitride semiconductor laser element according to the embodiment before aging is performed.

FIG. 6B is a graph showing reflectances relative to the film thicknesses of the dielectric multilayer film included in the nitride semiconductor laser element according to the embodiment after aging is performed.

FIG. 6C is a graph showing amounts of change in reflectances relative to the film thicknesses of the dielectric multilayer film included in the nitride semiconductor laser element according to the embodiment before and after aging is performed.

FIG. 7 is a diagram illustrating relationships between film thicknesses of a second dielectric film and a third dielectric film and reflectances of the dielectric multilayer film.

FIG. 8A is a graph showing reflectances relative to the film thicknesses of the dielectric multilayer film included in the nitride semiconductor laser element according to the embodiment before aging is performed.

FIG. 8B is a graph showing reflectances relative to the film thicknesses of the dielectric multilayer film included in the nitride semiconductor laser element according to the embodiment before aging is performed.

FIG. 8C is a graph showing reflectances relative to the film thicknesses of the dielectric multilayer film included in the nitride semiconductor laser element according to the embodiment before aging is performed.

FIG. 8D is a graph showing reflectances relative to the film thicknesses of the dielectric multilayer film included in the nitride semiconductor laser element according to the embodiment before aging is performed.

FIG. 8E is a graph showing reflectances relative to the film thicknesses of the dielectric multilayer film included in the nitride semiconductor laser element according to the embodiment before aging is performed.

FIG. 8F is a graph showing reflectances relative to the film thicknesses of the dielectric multilayer film included in the nitride semiconductor laser element according to the embodiment before aging is performed.

FIG. 9A is a graph showing amounts of change in reflectances relative to the film thicknesses of the dielectric multilayer film included in the nitride semiconductor laser element according to the embodiment before and after aging is performed.

FIG. 9B is a graph showing amounts of change in reflectances relative to the film thicknesses of the dielectric multilayer film included in the nitride semiconductor laser element according to the embodiment before and after aging is performed.

FIG. 9C is a graph showing amounts of change in reflectances relative to the film thicknesses of the dielectric multilayer film included in the nitride semiconductor laser element according to the embodiment before and after aging is performed.

FIG. 9D is a graph showing amounts of change in reflectances relative to the film thicknesses of the dielectric multilayer film included in the nitride semiconductor laser element according to the embodiment before and after aging is performed.

FIG. 9E is a graph showing amounts of change in reflectances relative to the film thicknesses of the dielectric multilayer film included in the nitride semiconductor laser element according to the embodiment before and after aging is performed.

FIG. 9F is a graph showing amounts of change in reflectances relative to the film thicknesses of the dielectric multilayer film included in the nitride semiconductor laser element according to the embodiment before and after aging is performed.

FIG. 10 is a diagram illustrating relationships between the film thicknesses of the dielectric multilayer film according to the embodiment and film thickness variations of the dielectric multilayer film according to the embodiment.

FIG. 11A is a graph showing amounts of change in reflectances relative to the film thicknesses of the dielectric multilayer film included in the nitride semiconductor laser element according to the embodiment before and after aging is performed.

FIG. 11B is a graph showing amounts of change in reflectances relative to the film thicknesses of the dielectric multilayer film included in the nitride semiconductor laser element according to the embodiment before and after aging is performed.

FIG. 11C is a graph showing amounts of change in reflectances relative to the film thicknesses of the dielectric multilayer film included in the nitride semiconductor laser element according to the embodiment before and after aging is performed.

FIG. 11D is a graph showing amounts of change in reflectances relative to the film thicknesses of the dielectric multilayer film included in the nitride semiconductor laser element according to the embodiment before and after aging is performed.

FIG. 11E is a graph showing amounts of change in reflectances relative to the film thicknesses of the dielectric multilayer film included in the nitride semiconductor laser element according to the embodiment before and after aging is performed.

FIG. 11F is a graph showing amounts of change in reflectances relative to the film thicknesses of the dielectric multilayer film included in the nitride semiconductor laser element according to the embodiment before and after aging is performed.

FIG. 12 is a graph showing reflectances of the dielectric multilayer film relative to wavelengths of the nitride semiconductor laser element according to the embodiment.

### DESCRIPTION OF EMBODIMENTS

Hereinafter, embodiments according to the present disclosure will be described with reference to the drawings. Note that the embodiments described below each show a specific example of the present disclosure. The numerical values, shapes, materials, structural elements, the arrangement and connection of the structural elements, etc. in the following embodiments are mere examples, and therefore do not intend to limit the present disclosure.

In addition, the drawings are schematic diagrams and do not necessarily provide strictly accurate illustrations. Accordingly, the drawings do not necessarily coincide with one another in terms of scales and the like. Throughout the drawings, the same reference numeral is given to substantially the same structural element, and redundant description is omitted or simplified.

In the embodiments below, terms “upper/above” and “lower/below” do not define an upward direction (vertically upward direction) and a downward direction (vertically downward direction), respectively, in absolute spatial cognition. These terms are used as terms specified according to a relative positional relationship based on a stacking order in a stacked configuration. In addition, the terms “upper/above” and “lower/below” are applied not only when two elements are disposed spaced apart with another element interposed therebetween, but also when the two elements are disposed in contact with each other.

In the present description and drawings, the X axis, Y axis, and Z axis represent three axes in a three-dimensional orthogonal coordinate system. Throughout the embodiments, the Z-axis direction indicates the vertical direction, and a direction perpendicular to the Z axis (a direction parallel to the X-Y plane) indicates the horizontal direction. Note that the positive direction of the Z axis indicates the vertically upward direction.

### Embodiment

### Overview

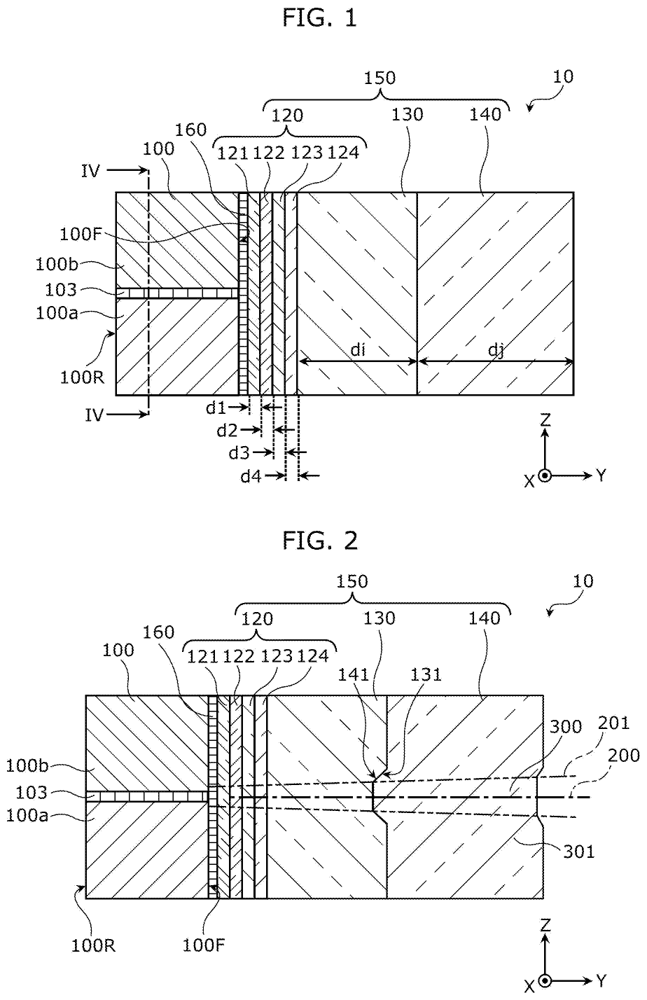

FIG. 1 is a cross sectional view schematically illustrating a configuration of nitride semiconductor laser element 10 according to an embodiment. FIG. 2 is a diagram schematically illustrating one example of deformation of dielectric films when nitride semiconductor laser element 10 according to the embodiment emits laser light 201. Note that FIG. 1 and FIG. 2 each are a cross sectional view taken along line I-I shown in FIG. 4 that will be described later.

Nitride semiconductor laser element 10 includes stacked structure 100 including first conductivity type semiconductor layer 100a, second conductivity type semiconductor layer 100b, and active layer 103 that is interposed between first conductivity type semiconductor layer 100a and second conductivity type semiconductor layer 100b and emits laser light 201. Nitride semiconductor laser element 10 has front end face (front-side end face) 100F on which dielectric multilayer film 150 is formed for causing laser light 201 to resonate inside stacked structure 100 to be effectively emitted from front end face 100F. Dielectric multilayer film 150 includes, for example, first dielectric film 120, second dielectric film 130, and third dielectric film 140. Specifically, on front end face 100F of stacked structure 100, first dielectric film 120, second dielectric film 130, and third dielectric film 140 are disposed in the stated order.

First dielectric film 120 is a film that protects front end face 100F, and prevents oxidation of front end face 100F due to diffusion of oxygen from outside. Each of second dielectric film 130 and third dielectric film 140 is a film for adjusting a reflectance.

First dielectric film 120, second dielectric film 130, and third dielectric film 140 each have a film thickness that is approximately uniformly formed with respect to front end face 100F.

Conventionally, a thickness distribution of dielectric multilayer film 150 need not be taken into account for designing a reflectance of dielectric multilayer film 150. A film thickness and a material of dielectric multilayer film 150 have been designed such that a reflectance reaches the maximal value or the minimal value relative to an oscillation wavelength of laser light 201 to be emitted from stacked structure 100.

In recent years, a blue-violet high-power laser element whose oscillation wavelength is approximately 405 nm and whose optical output of laser light 201 is at least 1 W is available. The inventors of the present application have found an alteration in a film of dielectric multilayer film 150 which is in the vicinity of a portion (light-emitting point) of front end face 100F from which laser light 201 is emitted when aging (i.e., continued emission of laser light 201) is performed for many hours in the above-described blue-violet high-power laser element.

For example, as illustrated in FIG. 2, there is a case where second dielectric film 130 and third dielectric film 140 deform due to absorption of laser light 201 emitted from stacked structure 100.

For example, emission of laser light 201 from stacked structure 100 causes the film thickness of each of second dielectric film 130 and third dielectric film 140 to be different in film thickness 300 that is a portion through which laser light 201 passes and film thickness 301 that is a portion through which laser light 201 does not pass. In other words, emission of laser light 201 changes film thicknesses 300 and 301 of each of second dielectric film 130 and third dielectric film 140.

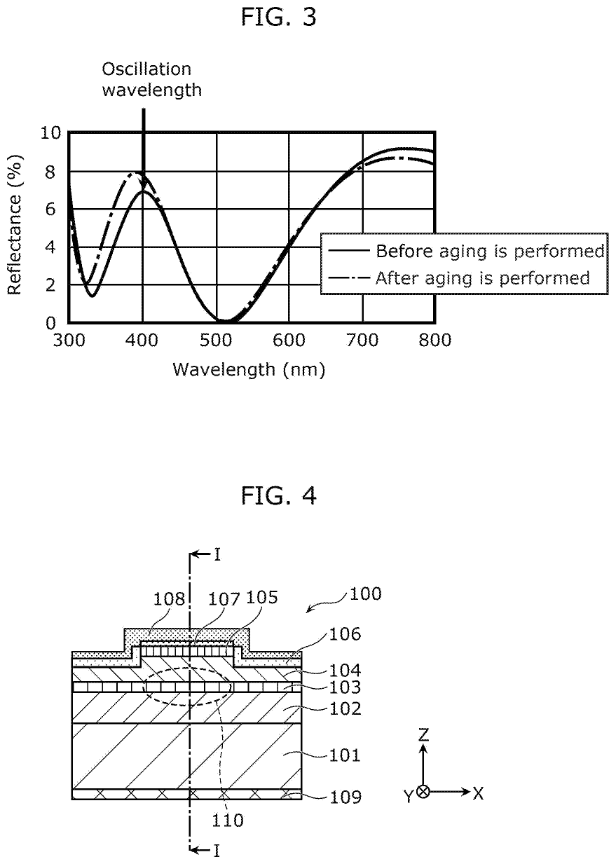

FIG. 3 is a graph showing reflectances of a dielectric multilayer film relative to wavelengths of a nitride semiconductor laser element according to a comparative example. The nitride semiconductor laser element according to the comparative example and nitride semiconductor laser element 10 according to the embodiment are the same except for materials used for dielectric multilayer films and film thicknesses and refractive indices of the dielectric multilayer films. The reflectance before aging as shown in FIG. 3 indicates a reflectance of light in a state in which a dielectric multilayer film is not deformed due to laser light 201 like dielectric multilayer film 150 illustrated in FIG. 1, for example. In contrast, the reflectance after aging as shown in FIG. 3 indicates a reflectance of light in a state in which the dielectric multilayer film is deformed due to laser light 201 like dielectric multilayer film 150 illustrated in FIG. 2, for example.

As illustrated in FIG. 3, positions of peaks at around a wavelength of 400 nm are different between the reflectance before aging is performed and the reflectance after aging is performed. Specifically, absorption of laser light has increased a reflectance of the dielectric multilayer film according to the comparative example by approximately 1.5% at the reflectance peak at around the wavelength of 400 nm. For this reason, an optical property (specifically, an optical output) of the nitride semiconductor laser element according to the comparative example is different before and after aging is performed. Accordingly, if nitride semiconductor laser element 10 is continuously used, the optical property changes in accordance with the passage of time, for example.

As a result of conducting in-depth study, the inventors of the present application have found that appropriately set materials, film thicknesses, and refractive indices for dielectric multilayer film 150 included in nitride semiconductor laser element 10 can prevent a change in the optical property. Specifically, the inventors of the present application have found the presence of a film whose film thickness increases and a film whose film thickness decreases during the performance of aging. In view of the above, the inventors of the present application have found that an appropriate combination of a film whose film thickness increases and a film whose film thickness decreases during the performance of aging can prevent the change in a reflectance even if the film thicknesses change during the performance of aging.

Hereinafter, a configuration and an optical property of nitride semiconductor laser element 10 according to the embodiment will be described in detail.

Note that, in the description below, emission of laser light 201 from stacked structure 100 may be simply called aging.

### Configuration

A configuration of nitride semiconductor laser element 10 will be described with reference to FIG. 1 and FIG. 4.

FIG. 4 is a cross sectional view of nitride semiconductor laser element 10 according to the embodiment which is taken along line IV-IV shown in FIG. 1.

Nitride semiconductor laser element 10 is a nitride semiconductor light-emitting element that emits laser light 201.

Nitride semiconductor laser element 10 includes stacked structure 100 and dielectric multilayer film 150.

Stacked structure 100 is a stacked body that includes a plurality of semiconductor layers including waveguide 110. Moreover, stacked structure 100 has front end face 100F and rear end face (rear-side end face) 100R that are a pair of resonator end faces opposed to each other. Dielectric multilayer film 150 is disposed on at least one end face of the pair of resonator end faces. In this embodiment, dielectric multilayer film 150 is disposed on front end face 100F.

Stacked structure 100 includes base 101, first semiconductor layer 102, active layer 103, second semiconductor layer 104, contact layer 105, insulating layer 106, second electrode 107, pad electrode 108, and first electrode 109. First conductivity type semiconductor layer 100a illustrated in FIG. 1 includes base 101 and first semiconductor layer 102. Second conductivity type semiconductor layer 100b illustrated in FIG. 1 includes second semiconductor layer 104 and contact layer 105. Note that, in FIG. 1, illustrations of insulating layer 106, second electrode 107, pad electrode 108, and first electrode 109 are omitted. In this embodiment, stacked structure 100 includes a gallium nitride-based material that is one example of nitride materials. With this, it is possible to realize nitride semiconductor laser element 10 having an optical property in which laser light 201 whose wavelength is in a band ranging approximately from 390 nm to 420 nm and whose optical output ranges approximately from 3 W to 10 W is emitted when a current applied to stacked structure 100 ranges from 2 A to 10 A and a voltage applied to stacked structure 100 ranges from 4 V to 6 V. As described above, nitride semiconductor laser element 10 emits laser light 201 of at least 1 W in this embodiment. In addition, nitride semiconductor laser element 10 has an oscillation wavelength of at most 420 nm. More specifically, stacked structure 100 emits laser light 201 whose peak wavelength is 400 nm.

Moreover, optical density of laser light 201 is at least 0.1 W/μm, for example. Note that the optical density is derived by dividing an optical output of laser light 201 by a stripe width. The stripe width here indicates, for example, a breadth (a length in the X axis direction in this embodiment) of a ridge that will be described later. The width of the ridge (hereinafter, called as a stripe width) ranges approximately from 30 μm to 100 μm, for example.

The resonator length (a length in the Y axis direction in this embodiment) of stacked structure 100 ranges from 1200 μm to 5000 μm, for example.

Note that the optical property of nitride semiconductor laser element 10 is not limited to the above. For example, nitride semiconductor laser element 10 may have an optical property in which laser light 201 whose wavelength is in a band ranging approximately from 365 nm to 390 nm and whose optical output ranges approximately from 1 W to 5 W is emitted when a current applied to stacked structure 100 ranges from 2 A to 10 A and a voltage applied to stacked structure 100 ranges from 3.5 V to 6 V. In this case, the stripe width ranges approximately from 8 μm to 100 μm, for example. Moreover, in this case, the resonator length of stacked structure 100 ranges from 800 μm to 5000 μm, for example.

Base 101 is a plate-like member that is a base material of stacked structure 100. In this embodiment, base 101 is a gallium nitride (GaN) monocrystalline base whose thickness is 100 μm. Note that the thickness of base 101 is not limited to 100 μm. Base 101 may have a thickness ranging from 50 μm to 120 μm, for example. Moreover, a material that base 101 includes is not limited to a GaN monocrystal. Base 101 may include sapphire, silicon carbide (SiC), etc.

First semiconductor layer 102 is a first conductivity type semiconductor layer disposed above base 101. In this embodiment, first semiconductor layer 102 is an n-type semiconductor layer disposed on one principal surface of base 101, and includes an n-type dad layer. The n-type dad layer includes n-aluminum gallium nitride (AlGaN). Note that the configuration of the n-type dad layer is not limited to the above-described configuration.

Active layer 103 is a light-emitting layer that is disposed above first semiconductor layer 102. In this embodiment, active layer 103 is a quantum well active layer in which well layers each including indium gallium nitride (InGaN) and barrier layers each including GaN are alternately stacked. Active layer 103 includes two well layers. Inclusion of active layer 103 as described above allows nitride semiconductor laser element 10 to emit blue laser light having a wavelength of about 400 nm. The configuration of active layer 103 is not limited to the above-described configuration as long as active layer 103 is a quantum well active layer in which well layers and barrier layers are alternately stacked. Note that active layer 103 may include a guide layer formed at least one of above and below the quantum well active layer.

Second semiconductor layer 104 is a second conductivity type semiconductor layer disposed above active layer 103. The second conductivity type is a conductivity type different from the first conductivity type. In this embodiment, second semiconductor layer 104 is a p-type semiconductor layer, and includes a p-type clad layer. The p-type clad layer is a superlattice layer in which 100 layers each including p-AlGaN and 100 layers each including GaN and having a thickness of 3 nm are alternately stacked. Note that the configuration of the p-type clad layer is not limited to the above-described configuration.

Waveguide 110 that is a wave guiding portion through which laser light 201 is guided is formed in first semiconductor layer 102, active layer 103, and second semiconductor layer 104.

Waveguide 110 is a portion through which laser light 201 is guided inside stacked structure 100. Waveguide 110 is formed in, for example, a portion of first semiconductor layer 102, a portion of active layer 103, and a portion of second semiconductor layer 104.

Contact layer 105 is a second conductivity type semiconductor layer that makes an ohmic contact with second electrode 107. In this embodiment, contact layer 105 is a p-type semiconductor layer, and includes p-GaN. Note that the configuration of contact layer 105 is not limited to the above-described configuration.

Moreover, in this embodiment, a ridge is formed in second semiconductor layer 104 and contact layer 105. An area of active layer 103 that corresponds with the ridge (i.e., an area of active layer 103 located below the ridge) is a light-emitting point, and laser light 201 is emitted therefrom.

First electrode 109 is an electrode disposed on a lower principal surface (i.e., the principal surface on which first semiconductor layer 102, etc. are not disposed) of base 101. First electrode 109 is a stacked film including titanium (Ti), platinum (Pt), and gold (Au) stacked in the stated order from base 101, for example. The configuration of first electrode 109 is not limited to the above-described configuration.

Second electrode 107 is an electrode disposed on contact layer 105. In this embodiment, second electrode 107 is a p-side electrode which makes an ohmic contact with contact layer 105. Pad electrode 108 is disposed on the p-side electrode.

Second electrode 107 is a stacked film including palladium (Pd) and Pt stacked in the stated order from contact layer 105, for example. The configuration of second electrode 107 is not limited to the above-described configuration.

Pad electrode 108 is a pad-like electrode that is disposed above second electrode 107. Pad electrode 108 is a stacked film including Ti and Au stacked in the stated order from second electrode 107, for example. Pad electrode 108 is disposed above and around the ridge. Note that the configuration of pad electrode 108 is not limited to the above-described configuration.

Although not illustrated in FIG. 4, stacked structure 100 may further include, for example, an insulating layer such as silicon oxide (SiO₂) film which surrounds a sidewall and the like of the ridge, in addition to the above-described layers.

Note that although stacked structure 100 in this embodiment is the so-called single emitter including one ridge (emitter), stacked structure 100 may be the so-called multi emitter including a plurality of ridges (e.g., approximately 60 ridges), In this case, the total optical output of laser light 201 emitted from below each of the plurality of ridges in stacked structure 100 ranges approximately from 100 W to 200 W.

Dielectric multilayer film 150 is a protective film that is disposed on front end face 100F of stacked structure 100. Specifically, dielectric multilayer film 150 protects front end face 100F of stacked structure 100, and reduces reflectance of front end face 100F for laser light 201. Dielectric multilayer film 150 includes first dielectric film 120, second dielectric film 130, and third dielectric film 140 in the stated order from the resonator end face (in this embodiment, front end face 100F) side.

Among first dielectric film 120, second dielectric film 130, and third dielectric film 140, first dielectric film 120 is a dielectric layer disposed closest to front end face 100F. First dielectric film 120 may include at least a single dielectric film including at least one of a nitride film and an oxynitride film. With this, diffusion of oxygen from outside dielectric multilayer film 150 into stacked structure 100 can be reduced. Accordingly, degradation of front end face 100F of stacked structure 100 can be prevented. Therefore, nitride semiconductor laser element 10 can be operated for a long term.

Moreover, first dielectric film 120 is directly connected with front end face 100F of stacked structure 100. Specifically, first dielectric film 120 is formed in contact with front end face 100F. Accordingly, the use of, as first dielectric film 120, a nitride film or an oxynitride film having the same crystallinity as stacked structure 100 can increase protection capability of front end face 100F.

For example, first dielectric film 120 includes n (n is a positive integer) protective films from a first protective film to an n^{th} protective film in the stated order from the front end face 100F side. In first dielectric film 120 according to the embodiment, n equals 4. Accordingly, first dielectric film 120 includes first protective film 121, second protective film 122, third protective film 123, and fourth protective film 124.

Among the plurality of protective films included in first dielectric film 120, first protective film 121 is a dielectric layer disposed closest to front end face 100F. In this embodiment, first protective film 121 includes a silicon nitride (SiN) film. More specifically, first protective film 121 includes a SiN film whose thickness d1 is approximately 0.5 nm. Note that the configuration of first protective film 121 is not limited to the above-described configuration. First protective film 121 may be, for example, another oxynitride film such as a silicon oxynitride (SiON) film.

Second protective film 122 is a dielectric film stacked on first protective film 121. In this embodiment, second protective film 122 includes an aluminum oxynitride (AlON) film. More specifically, second protective film 122 includes an AlON film whose thickness d2 is approximately 21 nm. Note that the configuration of second protective film 122 is not limited to the above-described configuration. Second protective film 122 may be, for example, another oxynitride film such as a SiON film or a nitride film such as an aluminum nitride (AlN) film and a SiN film.

Third protective film 123 is a dielectric film stacked on second protective film 122. In this embodiment, third protective film 123 includes an aluminum oxide (Al₂O₃) film whose thickness d3 is approximately 13 nm. Note that the configuration of third protective film 123 is not limited to the above-described configuration. Third protective film 123 may be, for example, another dielectric film such as a SiO₂ film, for example.

Fourth protective film 124 is a dielectric film stacked on third protective film 123. Fourth protective film 124 may include a dielectric film that includes at least one of a nitride film and an oxynitride film. In this embodiment, fourth protective film 124 includes an AlON film whose thickness d4 is approximately 11 nm. Note that the configuration of fourth protective film 124 is not limited to the above-described configuration. Fourth protective film 124 may be, for example, another nitride film such as a SiN film and an AlN film or an oxynitride film such as a SiON film.

Second dielectric film 130 is a dielectric film stacked on the outside of first dielectric film 120. In this embodiment, second dielectric film 130 includes an Al₂O₃ film whose thickness di is approximately 167 nm.

Third dielectric film 140 is a dielectric film stacked on the outside of second dielectric film 130. In this embodiment, third dielectric film 140 includes a SiO₂ film whose thickness dj is approximately 58 nm.

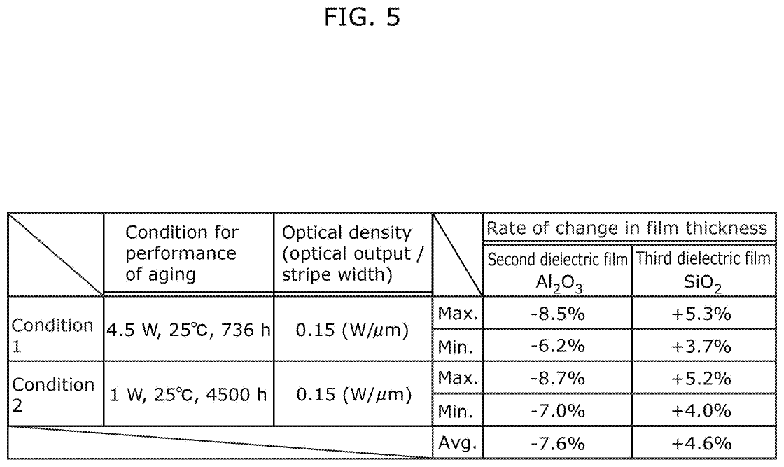

FIG. 5 is a table showing changes in film thicknesses according to conditions for performance of aging. Note that the peak wavelength (oscillation wavelength) of laser light 201 is 405 nm in both conditions 1 and 2.

As condition 1 shown in FIG. 5 indicates, when 4.5 W of laser light 201 was emitted from stacked structure 100 in a room temperature of 25° C. for 736 hours, the rate of change in the film thickness of second dielectric film 130 including an Al₂O₃ film was −8.5% at the maximum and −6.2% at the minimum due to a variation in a light intensity distribution of laser light 201. In addition, under condition 1, the rate of change in the film thickness of third dielectric film 140 including a SiO₂ film was +5.3% at the maximum and +3.7% at the minimum.

Note that the optical density in condition 1 is 0.15 (Wpm).

Moreover, as condition 2 shown in FIG. 5 indicates, when 1.0 W of laser light 201 was emitted from stacked structure 100 in a room temperature of 25° C. for 4500 hours, the rate of change in the film thickness of second dielectric film 130 including an Al₂O₃ film was −8.7% at the maximum and −7.0% at the minimum. In addition, under condition 2, the rate of change in the film thickness of third dielectric film 140 including a SiO₂ film was +5.2% at the maximum and +4.0% at the minimum.

Note that the optical density in condition 2 is 0.15 (Wpm).

The rate of change in the film thickness of second dielectric film 130 including an Al₂O₃ film under condition 1 and condition 2 has averaged −7.6%. In addition, the rate of change in the film thickness of third dielectric film 140 including a SiO₂ film under condition 1 and condition 2 has averaged +4.6%.

Moreover, in the case where the optical density was approximately 0.15 W/μm, the rate of change in the film thickness of second dielectric film 130 including an Al₂O₃ film has drastically decreased within the aging duration of 1000 hours, and has gradually decreased, although moderately, after the aging duration of 1000 hours. In addition, in the case where the optical density was approximately 0.15 W/μm, the rate of change in the film thickness of third dielectric film 140 including a SiO₂ film has drastically increased within the aging duration of 1000 hours, and has gradually increased, although moderately, after the aging duration of 1000 hours.

As has been described above, performance of aging has caused second dielectric film 130 including an Al₂O₃ film to shrink, and thus the film thickness has decreased. A film including an Al₂O₃ film is amorphous that includes several percent of argon (Ar) in a state (as-depo.) immediately after the film is formed. However, the film including an Al₂O₃ film in the as-depo. is thought to shrink due to desorption of Ar caused by an optical load applied as a result of performance of aging, and thus the film thickness has decreased.

In contrast, performance of aging has caused third dielectric film 140 including a SiO₂ film to expand, and thus the film thickness has increased. Third dielectric film 140 including a SiO₂ film is thought to expand due to desorption of Ar included in second dielectric film 130 including Al₂O₃ and diffusion of the desorbed Ar into the SiO₂ film, and thus the film thickness has increased.

From the above, as a material to be included in a film which expands as a result of performance of aging, a material whose amorphous state is stable, and a material that has a degree of freedom in molecular binding and is likely to contain an impurity atom may be taken into account. The following exemplify such materials: SiO₂, boron trioxide (B₂O₃), phosphorus pentoxide (P₂O₅), and germanium dioxide (GeO₂). In this embodiment, third dielectric film 140 has an amorphous structure. Moreover, third dielectric film 140 includes any one of SiO₂, B₂O₃, P₂O₅, and GeO₂, for example.

In addition, as a material to be included in a film which shrinks as a result of performance of aging, a material whose crystalline state is more stable than that of an amorphous state, and a material whose interatomic bond is strong and which is unlikely to contain an impurity atom may be taken into account. The following exemplify such materials: Al₂O₃, tantalum pentoxide (Ta₂O₅), and zirconium dioxide (ZrO₂). Moreover, second dielectric film 130 includes any one of Al₂O₃, Ta₂O₅, and ZrO₂, for example.

As described above, one of second dielectric film 130 and third dielectric film 140 has a property that the film thickness decreases due to laser light 201 emitted from nitride semiconductor laser element 10. The other of second dielectric film 130 and third dielectric film 140 has a property that the film thickness increases due to laser light 201 emitted from nitride semiconductor laser element 10. In this embodiment, second dielectric film 130 has a property that the film thickness decreases due to laser light 201 emitted from nitride semiconductor laser element 10. Third dielectric film 140 has a property that the film thickness increases due to laser light 201 emitted from nitride semiconductor laser element 10. Specifically, upon receival of laser light 201 emitted from front end face 100F, the following are formed at an interface between second dielectric film 130 and third dielectric film 140: recess 131 in second dielectric film 130; and protrusion 141 in third dielectric film 140. Moreover, a change in the film thickness of each of second dielectric film 130 and third dielectric film 140 occurs on an optical path of laser light 201 (e.g., on optical axis 200 of laser light 201) emitted from front end face 100F, for example.

According to nitride semiconductor laser element 10 including dielectric multilayer film 150 that includes materials as described above, dielectric multilayer film 150 having a film thickness and a refractive index as will be described later has the rate of reduction in an optical output that is at most 20% even if laser light 201 is emitted for approximately 10000 hours.

Note that coating film 160 may be disposed between front end face 100F and dielectric multilayer film 150.

Coating film 160 is a film that protects front end face 100F, and is, for example, an aluminum oxynitride film. The aluminum oxynitride film may include crystalline aluminum nitride. Specifically, the aluminum oxynitride film may be crystalline aluminum nitride.

Note that a material to be used for coating film 160 is not limited to the above. For example, a material to be used for coating film 160 may be at least one of aluminum silicon nitride, aluminum gallium nitride, aluminum yttrium nitride, aluminum lanthanum nitride, aluminum silicon oxynitride, aluminum gallium oxynitride, aluminum yttrium oxynitride, and aluminum lanthanum oxynitride. Moreover, a material mentioned above may be used as a material for first dielectric film 120.

In addition, the above-described dielectric multilayer film 150 having a film thickness and a refractive index as will be described later has a reflectance ranging approximately from 4% to 20% relative to light whose wavelength is 400 nm. Moreover, the so-called antireflection (AR) coating technique may be applied to dielectric multilayer film 150 so that dielectric multilayer film 150 has a reflectance of at most 0.1% relative to light whose wavelength is 400 nm.

In addition, dielectric multilayer film 150 may be provided on rear end face 100R.

### Optical Property

Next, an optical property of nitride semiconductor laser element 10 according to the embodiment will be described.

In order to determine a condition under which a change in a reflectance is small even if a film thickness changes in dielectric multilayer film 150, the inventors of the present application have carried out optical simulations. In the following optical simulations, second dielectric film 130 is an Al₂O₃ film and third dielectric film 140 is a SiO₂ film.

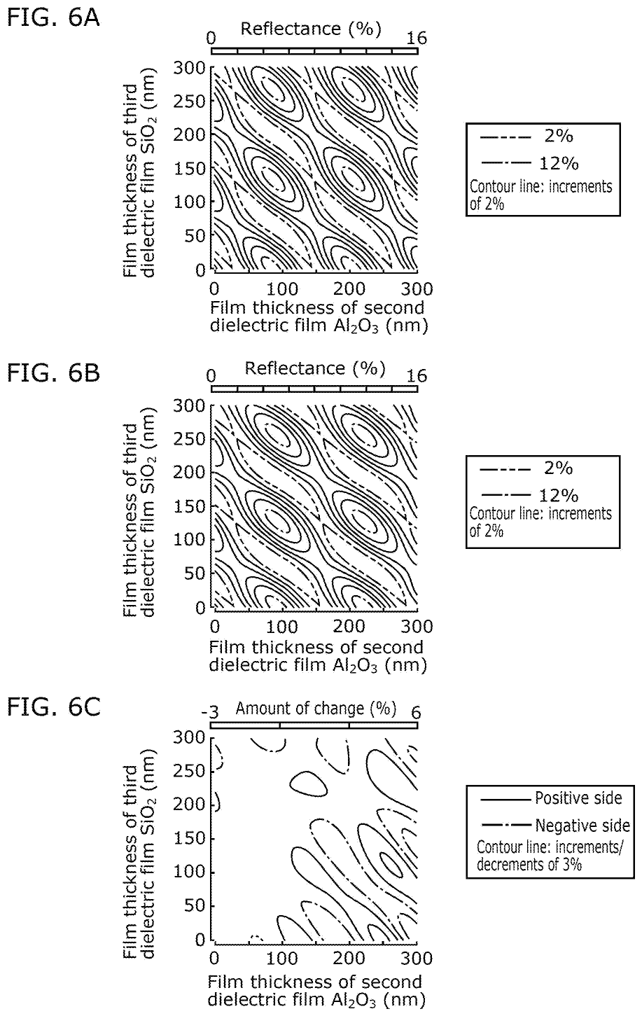

FIG. 6A is a graph showing reflectances relative to film thicknesses of dielectric multilayer film 150 included in nitride semiconductor laser element 10 according to the embodiment before aging is performed. FIG. 6B is a graph showing reflectances relative to the film thicknesses of dielectric multilayer film 150 included in nitride semiconductor laser element 10 according to the embodiment after aging is performed. FIG. 6C is a graph showing amounts of change in reflectances relative to the film thicknesses of dielectric multilayer film 150 included in nitride semiconductor laser element 10 according to the embodiment before and after aging is performed.

Note that, in FIG. 6A through FIG. 6C, conditions for first dielectric film 120 such as a film thickness and a refractive index are fixed. Moreover, in FIG. 6A through FIG. 6C, second dielectric film 130 is an Al₂O₃ film and third dielectric film 140 is a SiO₂ film. In FIG. 6A through FIG. 6C, a film thickness of each of the above films was caused to change in a range of from 0 nm to 300 nm for calculation of reflectances, and the reflectances are represented by contour lines.

Note that film thicknesses shown in FIG. 6B indicate film thicknesses before aging is performed. Specifically, in the graph shown in FIG. 6B, reflectances were calculated and represented by contour lines in the case where the film thickness of second dielectric film 130 is decreased by 7.6% with respect to the film thickness of second dielectric film 130 before aging is performed and the film thickness of third dielectric film 140 is increased by 4.6% with respect to the film thickness of third dielectric film 140 before the aging is performed.

In addition, FIG. 6C illustrates results obtained by calculating differences between reflectances before and after aging is performed. Specifically, the graph shown in FIG. 6C shows values obtained by subtracting reflectances shown in the graph of FIG. 6B from reflectances shown in the graph of FIG. 6A.

Moreover, in FIG. 6C, amounts of change in reflectances on the positive side are represented by contour lines in increments of 3% in order from +1.5%, and amounts of change in reflectances on the negative side are represented by contour lines in decrements of 3% in order from −1.5%.

From FIG. 6C, the presence of an area in which amounts of change in reflectances before and after the aging is performed range from −1.5% to +1.5% can be identified.

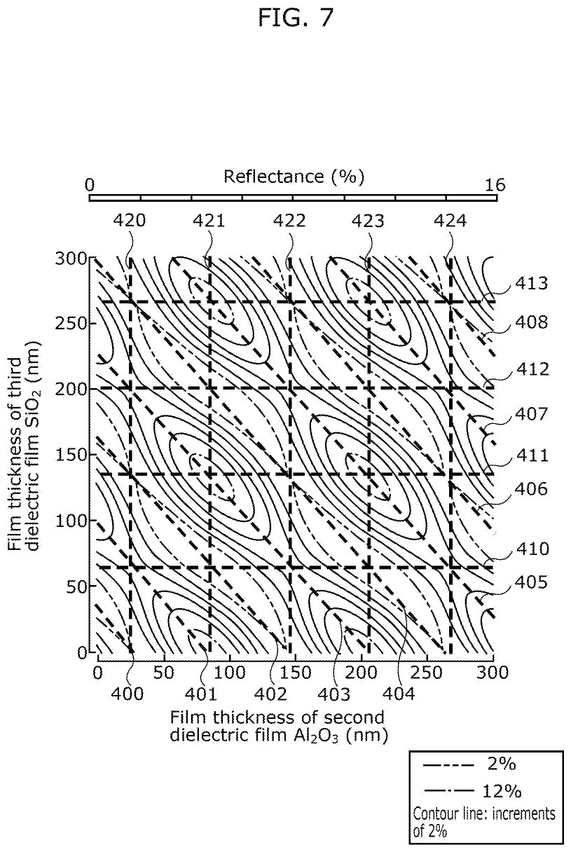

FIG. 7 is a diagram illustrating relationships between film thicknesses of second dielectric film 130 and third dielectric film 140 and reflectances of dielectric multilayer film 150. Note that the graph showing reflectances relative to the film thicknesses in FIG. 7 is the same as the graph shown in FIG. 6A.

The following expression (1) is satisfied, where (i) first dielectric film 120 includes one or more protective films (in this embodiment, four protective films) which are n protective films including a first protective film, a second protective film, and up to an n^{th} protective film in the stated order from the front end face 100F side, (ii) a refractive index and a film thickness of k^{th} (k is a positive integer) protective film are denoted by nk and dk, respectively, (iii) a refractive index and a film thickness of second dielectric film 130 are denoted by ni and di, respectively, (iv) a refractive index and a film thickness of third dielectric film 140 are denoted by nj and dj, respectively, and (v) a total sum of optical film thicknesses of the one or more protective films included in first dielectric film 120 is denoted by A.

[Math. 4]

A=Σnk×dk+ni×di+nj×dj Expression (1)

Moreover, in order from the left-hand side of the graph, dashed lines 400 through 407 shown in FIG. 7 satisfy the following expression (2).

A=m1×λ/4 Expression (2)

Note that m1 is a positive integer. For example, dashed line 400 is a straight line obtained by substituting 1 for m1 in expression (2). Similarly, dashed line 401 is a straight line obtained by substituting 2 for m1 in expression (2), for example. Similarly, dashed line 402 is a straight line obtained by substituting 3 for m1 in expression (2), for example. Similarly, dashed line 403 is a straight line obtained by substituting 4 for m1 in expression (2), for example. Similarly, dashed line 404 is a straight line obtained by substituting 5 for m1 in expression (2), for example. Similarly, dashed line 405 is a straight line obtained by substituting 6 for m1 in expression (2), for example. Similarly, dashed line 406 is a straight line obtained by substituting 7 for m1 in expression (2), for example. Similarly, dashed line 407 is a straight line obtained by substituting 8 for m1 in expression (2), for example.

Here, a reflectance of dielectric multilayer film 150 reaches the maximal value when m1 is an even number, and reaches the minimal value when m1 is an odd number.

Moreover, a change between the maximal value and the minimal value of reflectances cyclically corresponds with cos (4n×nj×dj/λ) that is a proportional term of a film thickness of a relation between an optical film thickness and a reflectance of a SiO₂ film that is third dielectric film 140 which derives from the Fresnel equations. In other words, multiplication of a film thickness and a refractive index (i.e., optical film thickness) of third dielectric film 140 that causes a reflectance of dielectric multilayer film 150 to reach the maximal value or the minimal value satisfies the following expression (3).

B=nj×dj=N1×λ/4 Expression (3)

Note that a refractive index and a film thickness of third dielectric film 140 are denoted by nj and dj, respectively. In addition, N1 is zero or a positive integer. For example, when N1=1, B is represented by dashed line 410. Moreover, when N1=2, B is represented by dashed line 411, for example. In addition, when N1=3, B is represented by dashed line 412, for example. Furthermore, when N1=4, B is represented by dashed line 413, for example.

The above-mentioned expression (3) is satisfied even if a film thickness of first dielectric film 120 is changed.

However, although a cycle between the maximal value and the minimal value is expressed by λ/4, a relationship between an optical film thickness and a reflectance of second dielectric film 130 is not necessarily expressed by an integer multiple of λ/4 since an optical film thickness that causes a reflectance to reach the maximal value or the minimal value is affected by a film thickness of first dielectric film 120.

Here, the following expression (4) is satisfied when D denotes the total sum of optical film thicknesses of first dielectric film 120 and second dielectric film 130.

[Math. 5]

D=Σnk×dk+ni×di Expression (4)

Moreover, a film thickness and a refractive index of second dielectric film 130 that cause a reflectance of dielectric multilayer film 150 to reach the maximal value or the minimal value satisfy the following expression (5).

D=N2×λ/4 Expression (5)

Note that a refractive index and a film thickness of second dielectric film 130 are denoted by ni and di, respectively. In addition, N2 is a positive integer. For example, when N2=1, D is represented by dashed line 420. Moreover, when N2=2, D is represented by dashed line 421, for example. In addition, when N2=3, D is represented by dashed line 422, for example. Furthermore, when N2=4, D is represented by dashed line 423, for example. In addition, when N2=5, D is represented by dashed line 424, for example.

The above-mentioned expression (5) is satisfied even if the ratio of a film thickness of first dielectric film 120 to a film thickness of second dielectric film 130 is changed.

Next, a change in a film thickness in the case where a film thickness of first dielectric film 120 is changed will be described.

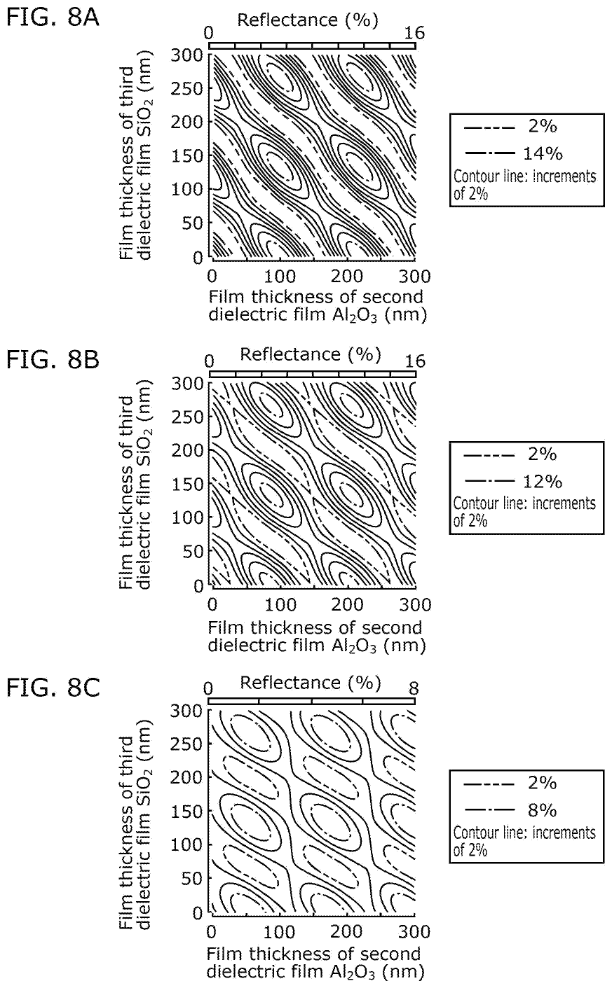

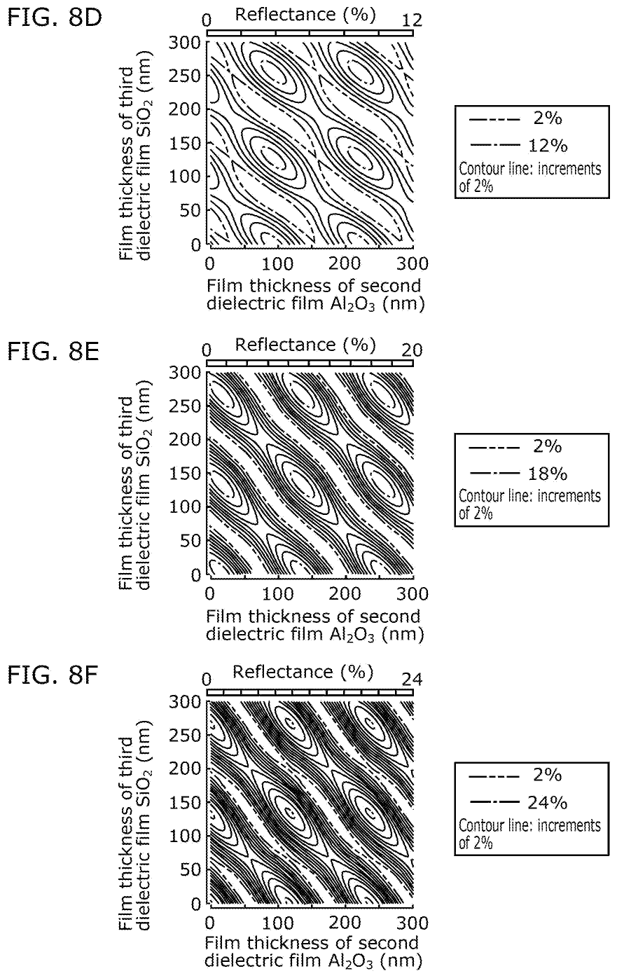

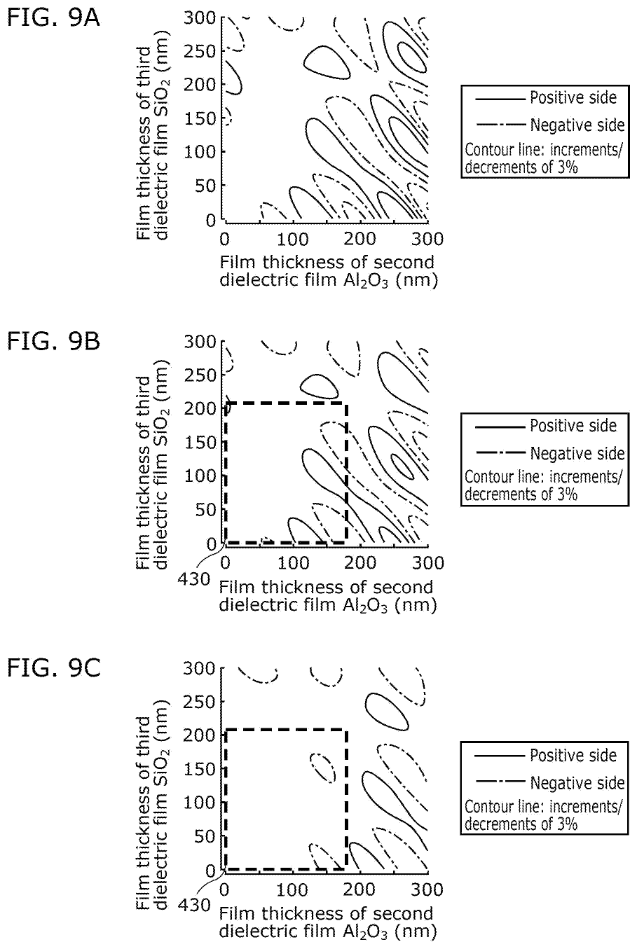

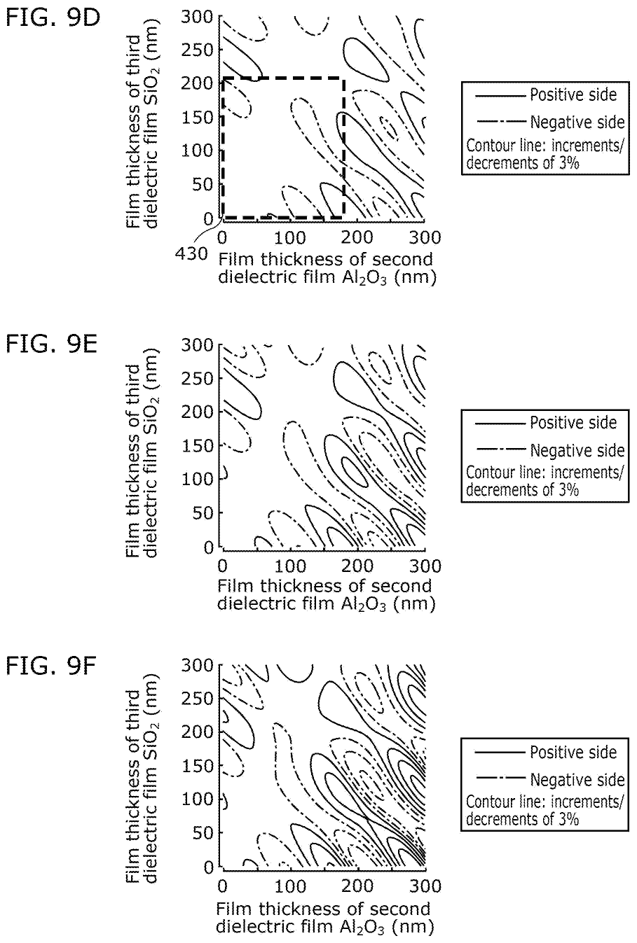

FIG. 8A through FIG. 8F each are a graph showing reflectances relative to the film thicknesses of dielectric multilayer film 150 included in nitride semiconductor laser element 10 according to the embodiment before aging is performed. FIG. 9A through FIG. 9F each are a graph showing amounts of change in reflectances relative to the film thicknesses of dielectric multilayer film 150 included in nitride semiconductor laser element 10 according to the embodiment before and after aging is performed.

Note that FIG. 8A and FIG. 9A each are a graph showing the case where an optical film thickness of first dielectric film 120 is set to λ/8. Moreover, FIG. 8B and FIG. 9B each are a graph showing the case where an optical film thickness of first dielectric film 120 is set to 3×λ/16. In addition, FIG. 8C and FIG. 9C each are a graph showing the case where an optical film thickness of first dielectric film 120 is set to λ/4. Furthermore, FIG. 8D and FIG. 9D each are a graph showing the case where an optical film thickness of first dielectric film 120 is set to 5×λ/16. Moreover, FIG. 8E and FIG. 9E each are a graph showing the case where an optical film thickness of first dielectric film 120 is set to 3×λ/8. In addition, FIG. 8F and FIG. 9F each are a graph showing the case where an optical film thickness of first dielectric film 120 is set to λ/2.

Note that A denotes an oscillation wavelength of laser light 201, and the oscillation wavelength in this embodiment is 400 nm.

Moreover, in FIG. 9A through FIG. 9F, amounts of change in reflectances on the positive side are represented by contour lines in increments of 3% in order from +1.5%, and amounts of change in reflectances on the negative side are represented by contour lines in decrements of 3% in order from −1.5%.

As shown in FIG. 9B, FIG. 9C, and FIG. 9D, amounts of change in reflectances range approximately from −1.5% to +1.5% within dashed line 430. Dashed line 430 indicates a range in which a film thickness of second dielectric film 130 is at most 3×λ/4 and a film thickness of third dielectric film 140 is at most 3×λ/4.

From the above, under a first film thickness condition, where (i) an optical film thickness of first dielectric film 120 (more specifically, the total sum of optical film thicknesses of a plurality of protective films included in first dielectric film 120) ranges from 3×λ/16 to 5×λ/16, (ii) an optical film thickness of second dielectric film 130 is at most 3×λ/4, and (iii) an optical film thickness of third dielectric film 140 is at most 3×λ/4, it is possible to reduce an amount of change in a reflectance of dielectric multilayer film 150 to range approximately from −1.5% to +1.5% even if aging is performed. In other words, first dielectric film 120 satisfies the following expression (6).

$$\begin{matrix}[ Math . 6 ] & \\ \frac{3 λ}{16} ≦ \sum nk \times dk ≦ \frac{5 λ}{16} & Expression ( 6 )\end{matrix}$$

Next, relationships between the film thicknesses of dielectric multilayer film 150 and film thickness variations of dielectric multilayer film 150 will be described.

When a plurality of nitride semiconductor laser elements 10 in which dielectric multilayer film 150 is formed on stacked structure 100 are manufactured, film thicknesses of dielectric multilayer films 150 included in the plurality of nitride semiconductor laser elements 10 do not perfectly correspond with one another due to variations that occur during manufacturing even if each of dielectric multilayer films 150 is intended to be manufactured to have the same film thickness.

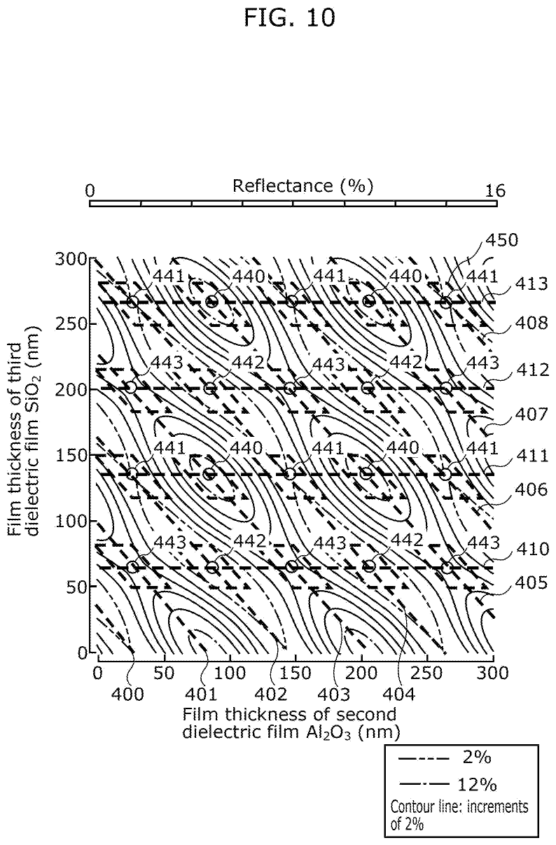

FIG. 10 is a diagram illustrating relationships between the film thicknesses of dielectric multilayer film 150 and film thickness variations of dielectric multilayer film 150. Note that the graph showing reflectances relative to the film thicknesses in FIG. 10 is the same as the graph shown in FIG. 6A.

From the maximal values, the minimal values, and saddle points of reflectances shown in the graph of FIG. 10, changes in reflectances relative to changes in the film thicknesses of dielectric multilayer film 150 are thought to be small, namely, stable. The maximal values, the minimal values, and the saddle points of reflectances shown in the graph of FIG. 10 each are any one of intersection points 440 through 443 at which dashed lines 400 through 404 shown in FIG. 10 and dashed lines 410 through 413 shown in FIG. 10 intersect. In other words, the maximal values, the minimal values, and the saddle points of reflectances in the graph shown in FIG. 10 represent film thicknesses each of which satisfies the above-mentioned expressions (1) and (3).

For example, when A in the above-mentioned expression (1) is an even number and B in the above-mentioned expression (3) is an even number, a reflectance indicates the maximal value and is represented by any one of the plurality of intersection points 440. For example, when A in the above-mentioned expression (1) is an even number and B in the above-mentioned expression (3) is an odd number, a reflectance indicates a saddle point and is represented by any one of the plurality of intersection points 441. For example, when A in the above-mentioned expression (1) is an odd number and B in the above-mentioned expression (3) is an even number, a reflectance indicates a saddle point and is represented by any one of the plurality of intersection points 442. For example, when A in the above-mentioned expression (1) is an odd number and B in the above-mentioned expression (3) is an odd number, a reflectance indicates the minimal value and is represented by any one of the plurality of intersection points 443.

Here, as a reflectance of dielectric multilayer film 150, it is suitable to select (i) intersection point 440 or intersection point 443 for realizing a high reflectance, and (ii) intersection point 441 or intersection point 442 for realizing a low reflectance.

As has been described above, changes in reflectances relative to the film thicknesses of dielectric multilayer film 150 can be made small when the reflectances are in the vicinity of intersection points 440 through 443. For example, changes in reflectances relative to the film thicknesses of dielectric multilayer film 150 can be made small when reflectances are within ranges of parallelogrammic areas surrounded by dashed lines 450 which indicate the vicinity of intersection points 440 through 443. The areas surrounded by dashed lines 450 as described above satisfy the following expressions (7) and (8).

$$\begin{matrix}[ Math . 7 ] & \\ A 1 \sum nk \times dk + ni \times di + nj \times dj = m 1 \times \frac{λ}{4} \pm \frac{λ}{16} & Expression ( 7 )\end{matrix}$$

$$B 1 = nj \times dj = m 2 \times λ / 4 \pm λ / 16 \qquad Expression ( 8 )$$

Note that both m1 and m2 are positive integers.

Under a second film thickness condition as described above, changes in reflectances relative to the film thicknesses of dielectric multilayer film 150 can be made small. Moreover, setting of m1 to an integer of at least 2 can make changes in reflectances relative to the film thicknesses of dielectric multilayer film 150 even smaller. In addition, when m2=1, in other words, when the following expression (9) is satisfied, changes in reflectances relative to the film thicknesses of dielectric multilayer film 150 can be made even smaller, for example.

3λ/16≤nj×dj≤5λ/16 Expression (9)

Moreover, from the relationship between the above-mentioned expression (4), the above-mentioned expression (5), and the parallelogrammic areas surrounded by dashed lines 450 which indicate the vicinity of intersection points 440 through 443, the following expression (10) is calculated.

$$\begin{matrix}[ Math . 8 ] & \\ \sum nk \times dk + ni \times di = m 3 \times \frac{λ}{4} \pm \frac{λ}{16} & Expression ( 10 )\end{matrix}$$

Note that m3 is a positive integer.

With this, when nitride semiconductor laser element 10 is driven (when nitride semiconductor laser element 10 is caused to emit laser light 201), a variation (change) in a reflectance of dielectric multilayer film 150 can also be prevented. For this reason, it is possible to prevent a variation in an optical output of nitride semiconductor laser element 10 during driving and degradation of nitride semiconductor laser element 10.

From the above, satisfaction of the first film thickness condition and the second film thickness condition can reduce an amount of change in a reflectance of dielectric multilayer film 150, and can make a change in a reflectance relative to a change in a film thickness of dielectric multilayer film 150 small, even if aging is performed. In other words, nitride semiconductor laser element 10 including dielectric multilayer film 150 that satisfies the first film thickness condition and the second film thickness condition as described above can prevent a change in the optical property.

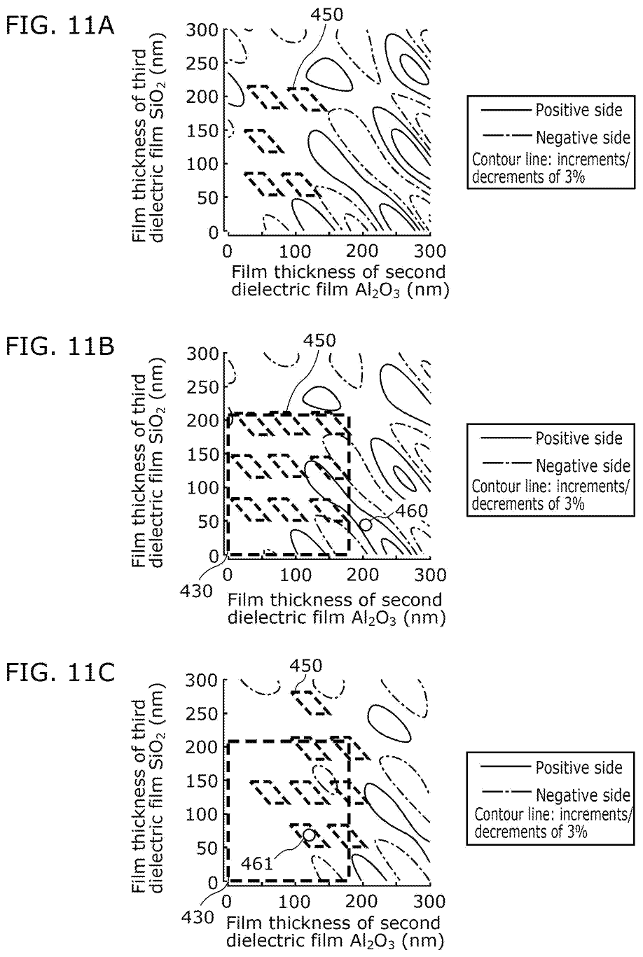

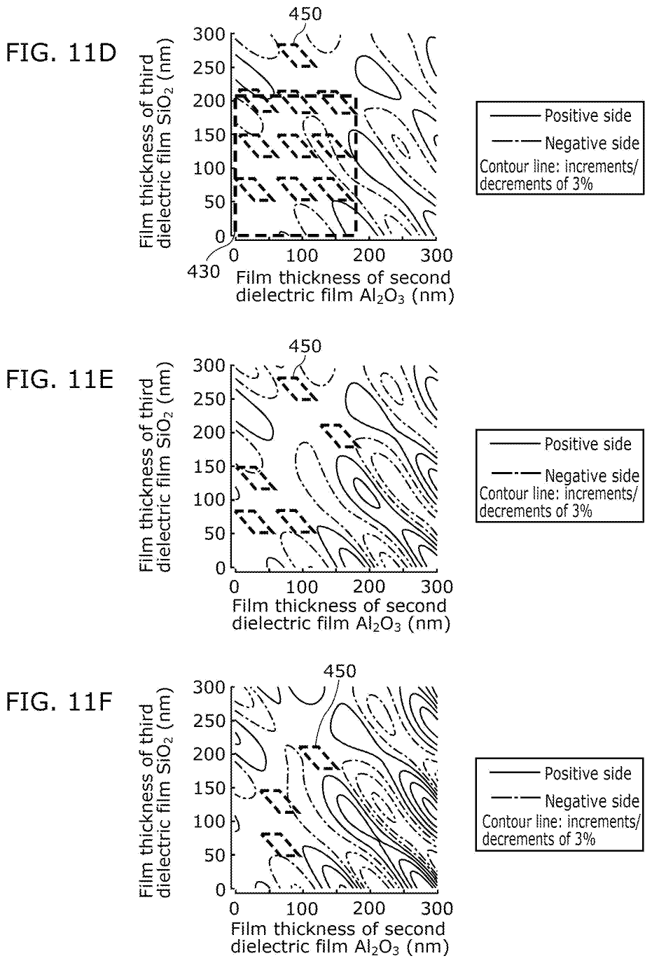

FIG. 11A through FIG. 11F each are a graph showing amounts of change in reflectances relative to the film thicknesses of dielectric multilayer film 150 included in nitride semiconductor laser element 10 according to the embodiment before and after aging is performed. Note that the graphs of FIG. 11A through FIG. 11F each of which showing reflectances relative to the film thicknesses are the same as the graphs shown in FIG. 9A through FIG. 9F.

Changes in reflectances relative to changes in the film thicknesses of dielectric multilayer film 150 can be made small when the reflectances are within ranges of areas surrounded by dashed lines 450 illustrated in FIG. 11A through FIG. 11F.

Moreover, even if aging is performed, amounts of change in reflectances of dielectric multilayer film 150 can be reduced when the reflectances are within ranges of quadrilateral areas surrounded by dashed lines 430 illustrated in FIG. 11B through FIG. 11D. In other words, a change in the optical property of dielectric multilayer film 150 can be further prevented when reflectances are within (i) ranges of the areas surrounded by dashed lines 430 illustrated in FIG. 116B through FIG. 11D, and (ii) ranges of the areas surrounded by dashed lines 450.

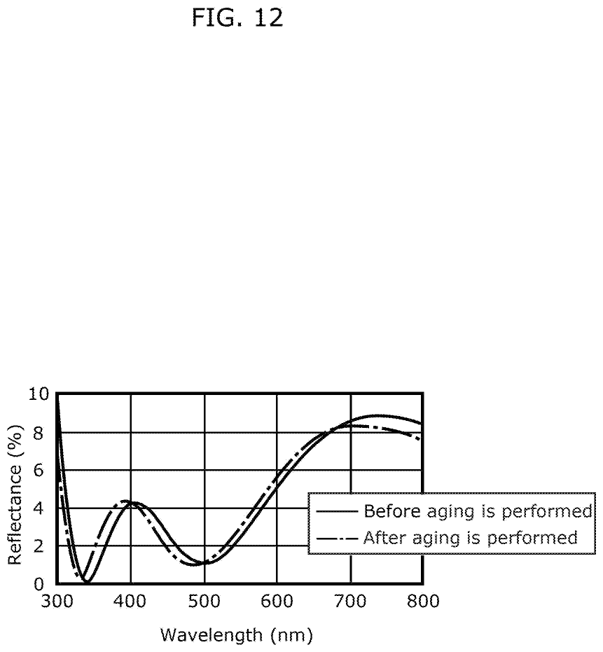

FIG. 12 is a graph showing reflectances of dielectric multilayer film 150 relative to wavelengths of nitride semiconductor laser element 10 according to the embodiment. Note that the graph of FIG. 12 shows reflectances of dielectric multilayer film 150 which satisfy a film thickness condition for dielectric multilayer film 150 at position 461 shown in FIG. 11C, namely, a film thickness condition within the area surrounded by dashed line 430 and the area surrounded by dashed line 450. Moreover, the graph of FIG. 3 shows reflectances of dielectric multilayer film 150 which satisfy a film thickness condition for dielectric multilayer film 150 at position 460 shown in FIG. 11B, namely, a film thickness condition outside the area surrounded by dashed line 430 and the areas surrounded by dashed lines 450.

As illustrated in FIG. 12, reflectances that satisfy the first film thickness condition and the second film thickness condition as described above have hardly changed with respect to, for example, light whose wavelength is 400 nm, before and after aging is performed.

### Advantageous Effects

As has been described above, nitride semiconductor laser element 10 includes: stacked structure 100 that includes a plurality of semiconductor layers (e.g., first semiconductor layer 102, active layer 103, and second semiconductor layer 104) including waveguide 110, and has a pair of resonator end faces (front end face 100F and rear end face 1008) that are opposed to each other; and dielectric multilayer film 150 disposed on at least one of the pair of the resonator end faces (front end face 100F in the embodiment).

Dielectric multilayer film 150 includes first dielectric film 120, second dielectric film 130, and third dielectric film 140 in the stated order from the resonator end face side. First dielectric film 120 includes n (n is a positive integer) protective films from a first protective film up to an n^{th} protective film in the stated order from the resonator end face side. In first dielectric film 120 according to the embodiment, n equals 4. Accordingly, first dielectric film 120 includes first protective film 121, second protective film 122, third protective film 123, and fourth protective film 124.

Nitride semiconductor laser element 10 satisfies the above-mentioned expressions (7), (8), and (6), where (i) a refractive index and a film thickness of a k^{th} (k is an integer satisfying 1≤k≤n) protective film in first dielectric film 120 are denoted by nk and dk, respectively, (ii) a refractive index and a film thickness of second dielectric film 130 are denoted by ni and di, respectively, (iii) a refractive index and a film thickness of third dielectric film 140 are denoted by nj and dj, respectively, (iv) m1 is an integer of at least 2, and (v) m2 is a positive integer.

With this, in dielectric multilayer film 150 included in nitride semiconductor laser element 10, an appropriate combination of a film thickness and a refractive index for each of the films included in dielectric multilayer film 150 can reduce a variation in a reflectance, even if the film thicknesses of dielectric multilayer film 150 vary. Therefore, it is possible to prevent a variation in the optical output of nitride semiconductor laser element 10 during driving, and degradation of nitride semiconductor laser element 10. In other words, nitride semiconductor laser element 10 can prevent degradation of the optical property.

Alternatively, nitride semiconductor laser element 10 satisfies the above-mentioned expressions (7) and (8). Moreover, one of second dielectric film 130 and third dielectric film 140 has a property that a film thickness decreases due to laser light 201 emitted from nitride semiconductor laser element 10, and the other of second dielectric film 130 and third dielectric film 140 has a property that a film thickness increases due to laser light 201 emitted from nitride semiconductor laser element 10.

With this, in dielectric multilayer film 150 included in nitride semiconductor laser element 10, an appropriate combination of a film thickness and a refractive index for each of the films included in dielectric multilayer film 150 can also reduce a variation in a reflectance, even if the film thicknesses of dielectric multilayer film 150 vary. For this reason, it is possible to prevent a variation in an optical output of nitride semiconductor laser element 10 during driving, and degradation of nitride semiconductor laser element 10.

Moreover, upon receival of laser light 201 emitted from the resonator end face, the following are formed at an interface between second dielectric film 130 and third dielectric film 140: recess 131 in second dielectric film 130; and protrusion 141 in third dielectric film 140, for example.

With this, an amount of change in the total film thickness of dielectric multilayer film 150 can be reduced even if dielectric multilayer film 150 is irradiated with laser light 201. For this reason, a change in a reflectance of dielectric multilayer film 150 is further prevented.

In addition, changes in the film thicknesses of second dielectric film 130 and third dielectric film 140 occur on an optical path of laser light 201 emitted from the resonator end face, for example.

With this, since changes in the film thicknesses of dielectric multilayer film 150 occur on an optical path of laser light 201, an amount of change in the total film thickness of dielectric multilayer film 150 in an area through which laser light 201 passes is reduced. For this reason, a change in a reflectance of dielectric multilayer film 150 is further prevented.

Moreover, third dielectric film 140 has an amorphous structure, for example.

With this, third dielectric film 140 having a property that the film thickness is increased by taking in an inert gas such as Ar included in second dielectric film 130 can be realized, for example.

In addition, nitride semiconductor laser element 10 further satisfies the above-mentioned expression (9), for example.

With this, an amount of change in the total film thickness of dielectric multilayer film 150 can be reduced even if dielectric multilayer film 150 is irradiated with laser light 201. For this reason, a change in a reflectance of dielectric multilayer film 150 is further prevented.

Moreover, nitride semiconductor laser element 10 has an oscillation wavelength of at most 420 nm, for example.

As described above, the configuration of dielectric multilayer film 150 is particularly effective as an end-face coating film in nitride semiconductor laser dement 10 that emits laser light 201 whose wavelength is at most 420 nm that is readily absorbed by dielectric multilayer film 150.

In addition, nitride semiconductor laser element 10 emits laser light 201 of at least 1 W, for example.

Changes in the film thicknesses of dielectric multilayer film 150 greatly depend on an optical output of laser light 201. For example, remarkable changes in the film thicknesses of dielectric multilayer film 150 occur when laser light 201 whose optical output is at least 1 W is used. For this reason, the configuration of dielectric multilayer film 150 is particularly effective as an end-face coating film in nitride semiconductor laser element 10 that emits laser light 201 of at least 1 W that is likely to affect a film thickness of dielectric multilayer film 150.

Moreover, nitride semiconductor laser element 10 satisfies the above-mentioned expression (10), where m3 is a positive integer, for example.

With this, an amount of change in the total film thickness of dielectric multilayer film 150 can be reduced even if dielectric multilayer film 150 is irradiated with laser light 201. For this reason, a change in a reflectance of dielectric multilayer film 150 is further prevented.

In addition, second dielectric film 130 includes any one of Al₂O₃, Ta₂O₅, and ZrO₂, and third dielectric film 140 includes any one of SiO₂, B₂O₃, P₂O₅, and GeO₂, for example.

With this, it is possible to combine, in dielectric multilayer film 150, a film whose film thickness decreases due to absorption of laser light 201 and a film whose film thickness increases due to absorption of laser light 201. For this reason, it is possible to prevent a variation in an optical output of nitride semiconductor laser element 10 during driving, and degradation of nitride semiconductor laser element 10.

Moreover, an aluminum oxynitride film is disposed in between the resonator end face and dielectric multilayer film 150, for example.

With this, an aluminum oxynitride film can prevent oxidation of the resonator end face in nitride semiconductor laser element 10. In addition, the above can reduce a dangling bond in the resonator end face and dielectric multilayer film 150. For this reason, degradation of dielectric multilayer film 150 can be prevented even if nitride semiconductor laser element 10 is driven to output a high optical output, for example.

In addition, the aluminum oxynitride film includes crystalline aluminum nitride, for example. In this case, the aluminum oxynitride film may be polycrystalline aluminum nitride, and may even be a film containing a large amount of oxygen in a grain boundary of a polycrystalline aluminum nitride.

With this, an aluminum oxynitride film including a crystal can further prevent oxidation of the resonator end face in nitride semiconductor laser element 10. Moreover, the above can reduce a dangling bond in the resonator end face and dielectric multilayer film 150. For this reason, degradation of dielectric multilayer film 150 can be further prevented even if nitride semiconductor laser element 10 is driven to output a high optical output, for example.

Moreover, in between the resonator end face and the dielectric multilayer film, a film including at least one of the following is disposed, for example: aluminum silicon nitride, aluminum gallium nitride, aluminum yttrium nitride, aluminum lanthanum nitride, aluminum silicon oxynitride, aluminum gallium oxynitride, aluminum yttrium oxynitride, or aluminum lanthanum oxynitride.

With this, in the similar manner as an aluminum oxynitride film, oxidation of the resonator end face in nitride semiconductor laser element 10 can also be prevented. In addition, the above can reduce a dangling bond in the resonator end face and dielectric multilayer film 150. For this reason, degradation of dielectric multilayer film 150 can be prevented even if nitride semiconductor laser element 10 is driven to output a high optical output, for example.

### Other Embodiments

Hereinbefore, a nitride semiconductor laser element according to the present disclosure have been described based on the above embodiments; however, the present disclosure is not limited to these embodiments. The present disclosure also encompasses: embodiments achieved by applying various modifications conceivable to those skilled in the art to each of the above embodiments; and embodiments achieved by optionally combining the structural elements and the functions of each of the above embodiments without departing from the essence of the present disclosure.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

nitride semiconductor laser element according to the present disclosure can be used as a light source for: industrial lighting, facility lighting, a headlight for vehicles, an industrial laser device such as a laser machining device, and an image displaying device such as a laser display and a projector.

1. A nitride semiconductor laser element comprising:
a stacked structure that includes a plurality of semiconductor layers including a waveguide, and has a pair of resonator end faces that are opposed to each other; and
a dielectric multilayer film disposed on a light-emitting end face of the pair of the resonator end faces, the light-emitting end face being a resonator end face from which light is emitted, wherein
the dielectric multilayer film includes a first dielectric film, a second dielectric film, and a third dielectric film in a stated order from a light-emitting end face side,
the first dielectric film includes n protective films from a first protective film up to an n^{th} protective film in a stated order from the light-emitting end face side, where n is a positive integer, and
the following expressions are satisfied:
$$\sum nk \times dk + ni \times di + nj \times dj = m 1 \times \frac{λ}{4} \pm \frac{λ}{16} ; \qquad [ Math . 1 ]$$
$$nj \times dj = m 2 \times λ / 4 \pm λ / 16 ; and$$
$$\frac{3 λ}{16} ≦ \sum nk \times dk ≦ \frac{5 λ}{16} , \qquad [ Math . 2 ]$$
where (i) a refractive index and a film thickness of a k^{th} protective film in the first dielectric film are denoted by nk and dk, respectively, where k is an integer satisfying 1≤k≤n, (ii) a refractive index and a film thickness of the second dielectric film are denoted by ni and di, respectively, (iii) a refractive index and a film thickness of the third dielectric film are denoted by nj and dj, respectively, (iv) m1 is an integer of at least 2, and (v) m2 is a positive integer.

2. A nitride semiconductor laser element comprising:
a stacked structure that includes a plurality of semiconductor layers including a waveguide, and has a pair of resonator end faces that are opposed to each other; and
a dielectric multilayer film disposed on a light-emitting end face of the pair of the resonator end faces, the light-emitting end face being a resonator end face from which light is emitted, wherein
the dielectric multilayer film includes a first dielectric film, a second dielectric film, and a third dielectric film in a stated order from a light-emitting end face side,
the first dielectric film includes n protective films from a first protective film up to an n^{th} protective film in a stated order from the light-emitting end face side, where n is an integer of at least 1,
the following expressions are satisfied:
$$\sum nk \times dk + ni \times di + nj \times dj = m 1 \times \frac{λ}{4} \pm \frac{λ}{16} ; and \qquad [ Math . 3 ]$$
$$nj \times dj = m 2 \times λ / 4 \pm λ / 16 ,$$
where (i) a refractive index and a film thickness of a k^{th} protective film in the first dielectric film are denoted by nk and dk, respectively, where k is an integer satisfying 1≤k≤n, (ii) a refractive index and a film thickness of the second dielectric film are denoted by ni and di, respectively, (iii) a refractive index and a film thickness of the third dielectric film are denoted by nj and dj, respectively, (iv) m1 is an integer of at least 2, and (v) m2 is a positive integer,
one of the second dielectric film and the third dielectric film has a property that a film thickness decreases due to laser light emitted from the nitride semiconductor laser element, and
an other of the second dielectric film and the third dielectric film has a property that a film thickness increases due to the laser light emitted from the nitride semiconductor laser element.

3. The nitride semiconductor laser element according to claim 1, wherein
upon receival of laser light emitted from the light-emitting end face, the following are formed at an interface between the second dielectric film and the third dielectric film: a recess in the second dielectric film; and a protrusion in the third dielectric film.

4. The nitride semiconductor laser element according to claim 1, wherein
a change in each film thickness occurs on an optical path of laser light emitted from the light-emitting end face.

5. The nitride semiconductor laser element according to claim 1, wherein
the third dielectric film has an amorphous structure.

6. The nitride semiconductor laser element according to claim 1, wherein the following expression is further satisfied:
3λ/16≤nj×dj≤5λ/16.

7. The nitride semiconductor laser element according to claim 1, wherein
the nitride semiconductor laser element has an oscillation wavelength of at most 420 nm.

13. The nitride semiconductor laser element according to claim 1, wherein
the nitride semiconductor laser element emits laser light of at least 1 W.

9. The nitride semiconductor laser element according to claim 1, wherein
the following expression is further satisfied:
$$\sum nk \times dk + ni \times di = m 3 \times \frac{λ}{4} \pm \frac{λ}{16} , \qquad [ Math . 4 ]$$
where m3 is a positive integer.

10. The nitride semiconductor laser element according to claim 1, wherein
the second dielectric film includes any one of aluminum oxide (Al₂O₃), tantalum pentoxide (Ta₂O₅), and zirconium dioxide (ZrO₂), and
the third dielectric film includes any one of silicon oxide (SiO₂), boron trioxide (B₂O₃), phosphorus pentoxide (P₂O₅), and germanium dioxide (GeO₂).

11. The nitride semiconductor laser element according to claim 1, wherein
an aluminum oxynitride film is disposed in between the light-emitting end face and the dielectric multilayer film.

12. The nitride semiconductor laser element according to claim 11, wherein
the aluminum oxynitride film includes crystalline aluminum nitride.

13. The nitride semiconductor laser element according to claim 1, wherein
the in between the light-emitting end face and the dielectric multilayer film, a film including at least one of the following is disposed: aluminum silicon nitride, aluminum gallium nitride, aluminum yttrium nitride, aluminum lanthanum nitride, aluminum silicon oxynitride, aluminum gallium oxynitride, aluminum yttrium oxynitride, or aluminum lanthanum oxynitride.

14. The nitride semiconductor laser element according to claim 2, wherein
the following expression is further satisfied:
$$\frac{3 λ}{16} ≦ \sum nk \times dk ≦ \frac{5 λ}{16} . \qquad [ Math . 5 ]$$

15. The nitride semiconductor laser element according to claim 1, wherein
the first dielectric film is in contact with the light-emitting end face.

16. The nitride semiconductor laser element according to claim 1, wherein
the n is a positive integer of at least 2.

17. The nitride semiconductor laser element according to claim 2, wherein
the upon receival of laser light emitted from the light-emitting end face, the following are formed at an interface between the second dielectric film and the third dielectric film: a recess in the second dielectric film; and a protrusion in the third dielectric film.

18. The nitride semiconductor laser element according to claim 2, wherein
the a change in each film thickness occurs on an optical path of laser light emitted from the light-emitting end face.

19. The nitride semiconductor laser element according to claim 2, wherein
the following expression is further satisfied:
3λ/16≤nj×dj≤5λ/16.

20. The nitride semiconductor laser element according to claim 2, wherein
the following expression is further satisfied:
$$\sum nk \times dk + ni \times di = m 3 \times \frac{λ}{4} \pm \frac{λ}{16} , \qquad [ Math . 6 ]$$
where m3 is a positive integer.
